(19) United States
(12) Patent Application Publication
(10) Pub. No.: US 2026/0293346 A1
(43) Pub. Date: Sep. 24, 2026

(54) PHOTODETECTOR AND RANGING DEVICE

(71) Applicant: SONY SEMICONDUCTOR SOLUTIONS CORPORATION, Kanagawa (JP)

(72) Inventors: Takeshi MATSUNUMA, Kanagawa (JP); Kiichi ISHIKAWA, Kanagawa (JP)

(73) Assignee: SONY SEMICONDUCTOR SOLUTIONS CORPORATION, Kanagawa (JP)

(21) Appl. No.: 19/474,181

(22) PCT Filed: Apr. 15, 2024
(86) PCT No.: PCT/JP2024/015036

§ 371 Date: Oct. 9, 2025

(30) Foreign Application Priority Data
Apr. 28, 2023 (JP) 2023-074996

(51) Int. Cl. H10F 39/00; G01S 7/481; G01S 17/931; H10F 30/225; H10F 39/18

(52) U.S. Cl. CPC H10F 39/806; G01S 7/4816; H10F 30/225; H10F 39/1825; H10F 39/1847; G01S 17/931

(57) ABSTRACT

Provided is a photodetector having high photodetection performance. The photodetector includes: a first photodetection unit configured to detect light in a first wavelength range; a second photodetection unit stacked with the first photodetection unit and configured to detect light in a second wavelength range different from the light in the first wavelength range; and one or a plurality of optical elements that is provided between the first photodetection unit and the second photodetection unit, and condenses the light in the second wavelength range that has passed through the first photodetection unit and guides the condensed light to the second photodetection unit.

### TECHNICAL FIELD

The present disclosure relates to a photodetector having a structure in which, for example, two photodetection units are stacked, and a ranging device including the photodetector.

### BACKGROUND ART

For example, a proposal has been made for a photodetector configured to simultaneously acquire both visible light and infrared light, to measure a distance to an object (for example, refer to Patent Literature 1).

### CITATION LIST

### Patent Literature

Patent Literature 1: Japanese Unexamined Patent Application Publication No. 2017-112169

### SUMMARY OF INVENTION

Now, what is desired for such a photodetector is enhanced photodetection performance.

Thus, a photodetector having high photodetection performance is desired.

A photodetector according to an embodiment of the present disclosure includes: a first photodetection unit configured to detect light in a first wavelength range; a second photodetection unit stacked with the first photodetection unit and configured to detect light in a second wavelength range different from the light in the first wavelength range; and one or a plurality of optical elements that is provided between the first photodetection unit and the second photodetection unit, and condenses the light in the second wavelength range that has passed through the first photodetection unit and guides the condensed light to the second photodetection unit.

In the photodetector according to the embodiment of the present disclosure, the one or the plurality of the optical elements is provided between the first photodetection unit and the second photodetection unit. The one or the plurality of the optical elements condenses the light in the second wavelength range that has passed through the first photodetection unit and guides the condensed light to the second photodetection unit. Thus, the light in the first wavelength range that has passed through the first photodetection unit does not leak out to a peripheral region but enters the predetermined second photodetection unit corresponding to the first photodetection unit.

### BRIEF DESCRIPTION OF DRAWINGS

FIG. 1A is a schematic configuration diagram illustrating an example of a photodetector according to a first embodiment of the present disclosure.

FIG. 1B is an illustrative diagram schematically illustrating a configuration example of a pixel unit illustrated in FIG. 1A.

FIG. 2 is a vertical cross-sectional view illustrating a configuration example of the photodetector illustrated in FIG. 1A.

FIG. 3A is a schematic cross-sectional view illustrating a first configuration example of a horizontal cross-section of the photodetector illustrated in FIG. 2.

FIG. 3B is a schematic cross-sectional view illustrating a second configuration example of a horizontal cross-section of the photodetector illustrated in FIG. 2.

FIG. 3C is a schematic cross-sectional view illustrating a third configuration example of a horizontal cross-section of the photodetector illustrated in FIG. 2.

FIG. 3D is a schematic cross-sectional view illustrating a fourth configuration example of a horizontal cross-section of the photodetector illustrated in FIG. 2.

FIG. 4 is a vertical cross-sectional view illustrating a configuration example of a photodetector according to a reference example.

FIG. 5A is a schematic cross-sectional view illustrating a first configuration example of a horizontal cross-section of the photodetector illustrated in FIG. 4.

FIG. 5B is a schematic cross-sectional view illustrating a second configuration example of a horizontal cross-section of the photodetector illustrated in FIG. 4.

FIG. 5C is a schematic cross-sectional view illustrating a third configuration example of a horizontal cross-section of the photodetector illustrated in FIG. 4.

FIG. 5D is a schematic cross-sectional view illustrating a fourth configuration example of a horizontal cross-section of the photodetector illustrated in FIG. 4.

FIG. 6 is a vertical cross-sectional view illustrating a second configuration example of the photodetector illustrated in FIG. 1A.

FIG. 7 is a vertical cross-sectional view illustrating a first modification example of the photodetector illustrated in FIG. 1A.

FIG. 8 is a vertical cross-sectional view illustrating a second modification example of the photodetector illustrated in FIG. 1A.

FIG. 9 is a vertical cross-sectional view illustrating a third modification example of the photodetector illustrated in FIG. 1a.

FIG. 10 is a vertical cross-sectional view illustrating a fourth modification example of the photodetector illustrated in FIG. 1A.

FIG. 11 is a first vertical cross-sectional view illustrating a configuration example of a photodetector according to a second embodiment of the present disclosure.

FIG. 12 is a schematic plan view illustrating an example of a plan configuration of metalenses illustrated in FIG. 11.

FIG. 13 is a second vertical cross-sectional view illustrating a configuration example of the photodetector according to the second embodiment of the present disclosure.

FIG. 14 is a vertical cross-sectional view illustrating a first modification example of the photodetector illustrated in FIG. 11.

FIG. 15 is a functional block diagram illustrating an example of an electronic device (ranging device) using the photodetector illustrated in FIG. 1 and the like.

FIG. 16 is a block diagram depicting an example of schematic configuration of a vehicle control system.

FIG. 17 is a diagram of assistance in explaining an example of installation positions of an outside-vehicle information detecting section and an imaging section.

### MODES FOR CARRYING OUT THE INVENTION

In the following, some embodiments of the present disclosure are described in detail with reference to the drawings. The following description is a specific example of the present disclosure, but the present disclosure is not limited to the following aspects. Moreover, the present disclosure is not limited to arrangement, dimensions, dimensional ratios, and the like of the constituent elements illustrated in the drawings. It is to be noted that the description is given in the following order.

### 0. Background

### 1. First Embodiment

A first example of a photodetector including a first photodetection unit that obtains visible light image information and a second photodetection unit as a direct TOF (dTOF) sensor that receives infrared light and obtains distance information.

### 1-1. Configuration

### 1-2. Workings and Effects

### 1-3. Modification Examples

### 2. Second Embodiment

A second example of a photodetector including a first photodetection unit that obtains visible light image information and a second photodetection unit as a dTOF sensor that receives infrared light and obtains distance information.

### 2-1. Configuration

### 2-2. Workings and Effects

### 2-3. Modification Examples

### 3. Application Examples

### 4. Applied Examples

### <0. Background>

First, description is given of the background that has led to the creation of the technology of the present disclosure. As described above, a proposal has already been made for a photodetector configured to simultaneously detect light in a plurality of different wavelength ranges, for example, visible light and infrared light. In such a photodetector, for example, a first photodetection unit and a second photodetection unit are stacked. The first photodetection unit is configured to detect visible light, and the second photodetection unit is configured to detect infrared light. The photodetector allows the first photodetection unit to detect visible light, while allowing the second photodetection unit to detect infrared light that has passed through the first photodetection unit. With such a configuration, it is possible to attain enhanced resolution as compared with a case where the first photodetection unit and the second photodetection unit are arranged in an in-plane direction.

However, in such a stacked structure, the light traveling in the stacking direction is diffused or diffracted when reaching the second photodetection unit after passing through the first photodetection unit. This sometimes causes a portion of the light to become leakage light leaking out to a peripheral region, without entering the second photodetection unit. Moreover, a portion of obliquely entering light that has obliquely entered the first photodetection unit and passed through the first photodetection unit sometimes becomes the leakage light leaking out to the peripheral region, without entering the second photodetection unit corresponding to the first photodetection unit. Furthermore, alternatively, when a relative position in the in-plane direction between the first photodetection unit and the second photodetection unit is deviated due to a manufacturing error or the like, similar leakage light is generated.

When such leakage light is generated, an amount of light entering the second photodetection unit decreases, causing a decline in detection sensitivity of the second photodetection unit. Furthermore, the entry of such leakage light into a photodetection unit of another pixel nearby causes so-called crosstalk.

Thus, in view of such a situation, the present applicant proposes, in the following, a new photodetector having good photodetection performance, such as high photodetection sensitivity and high resolution, while suppressing the occurrence of crosstalk.

### 1. First Embodiment

### <1-1. Configuration>

### <Overall Configuration Example>

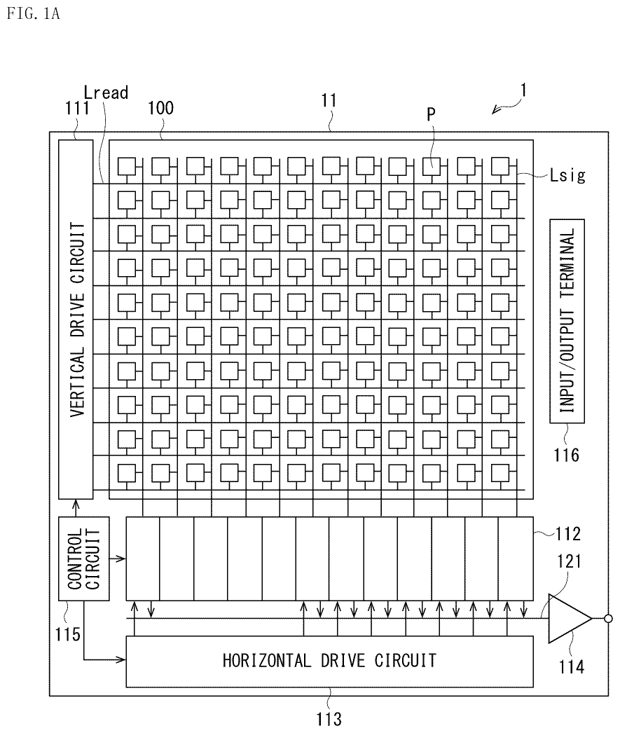

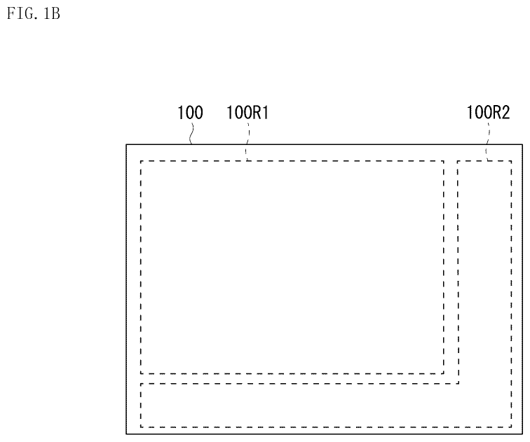

FIG. 1A illustrates an overall configuration example of a photodetector 1 according to an embodiment of the present disclosure. The photodetector 1 is, for example, a CMOS (Complementary Metal Oxide Semiconductor) image sensor. The photodetector 1 takes in entering light (image light) from an object through, for example, an optical lens system, converts the entering light converging on an imaging surface into an electric signal in units of pixels, and outputs the electric signal as a pixel signal. The photodetector 1 includes a pixel unit 100 as an imaging area, a vertical drive circuit 111, column signal processing circuits 112, a horizontal drive circuit 113, an output circuit 114, a control circuit 115, and an input/output terminal 116 on, for example, a semiconductor substrate 21. The vertical drive circuit 111, the column signal processing circuits 112, the horizontal drive circuit 113, the output circuit 114, the control circuit 115, and the input/output terminal 116 are disposed in a peripheral region of the pixel unit 100.

FIG. 1B schematically illustrates a configuration example of the pixel unit. As illustrated in FIG. 1B, the pixel unit 100 includes, for example, an effective region 100R1 and a peripheral region 100R2. The effective region 100R1 includes a plurality of pixels P in a two-dimensional array in a matrix. The peripheral region 100R2 is located around the effective region 100R1. In the effective region 100R1 of the pixel unit 100, for example, a plurality of pixel rows and a plurality of pixel columns are provided. The plurality of the pixel rows each includes a plurality of the pixels P arranged in a horizontal direction (the horizontal direction in the surface of the paper). The plurality of the pixel columns each includes a plurality of the pixels P arranged in a vertical direction (the vertical direction in the surface of the paper). In the pixel unit 100, for example, one pixel driving line Lread (a row selection line and a reset control line) is wired for each pixel row, and one vertical signal line Lsig is wired for each pixel column. The pixel driving line Lread transmits a driving signal for reading out signals from each pixel P. The end portions of the plurality of the pixel driving lines Lread are coupled to respective output terminals corresponding to the respective pixel rows of the vertical drive circuit 111.

The vertical drive circuit 111 includes shift registers, address decoders, or the like, and serves as a pixel driving unit that drives each pixel P in the pixel unit 100, for example, in units of the pixel rows. The signals to be outputted from the respective pixels P of the pixel row selected and scanned by the vertical drive circuit 111 are supplied to the column signal processing circuits 112 through the respective vertical signal lines Lsig.

The column signal processing circuits 112 include an amplifier, a horizontal selection switch, and the like provided for each vertical signal line Lsig.

The horizontal drive circuit 113 includes shift registers, address decoders, and the like, and scans and sequentially drives the horizontal selection switches of the column signal processing circuits 112. By the selection and the scanning by the horizontal drive circuit 113, the signals of the respective pixels P to be transmitted through the respective vertical signal lines Lsig are sequentially outputted to the horizontal signal line 121, and transmitted to the outside of the semiconductor substrate 21 through the horizontal signal line 121.

The output circuit 114 performs signal processing on the signals sequentially supplied from each of the column signal processing circuits 112 through the horizontal signal line 121 and outputs the resultant signals. For example, the output circuit 114 may perform only buffering, or may perform black level adjustment, column variation correction, various kinds of digital signal processing, and the like.

Circuit portions including the vertical drive circuit 111, the column signal processing circuits 112, the horizontal drive circuit 113, the horizontal signal line 121, and the output circuit 114 may be formed directly on the semiconductor substrate 21 or may be disposed in an external control IC. Moreover, those circuit portions may be formed on another substrate coupled by a cable or the like.

The control circuit 115 receives a clock supplied from the outside of the semiconductor substrate 21, data that commands an operation mode, and the like. Moreover, the control circuit 115 also outputs data such as internal information regarding the pixels P as an imaging element. The control circuit 115 further includes a timing generator that generates various kinds of timing signals. The control circuit 115 makes a driving control of the peripheral circuits such as the vertical drive circuit 111, the column signal processing circuits 112, and the horizontal drive circuit 113 based on the various kinds of the timing signals generated by the timing generator.

The input/output terminal 116 exchanges signals with the outside.

### <Cross-Sectional Configuration Example of Pixel Unit 100>

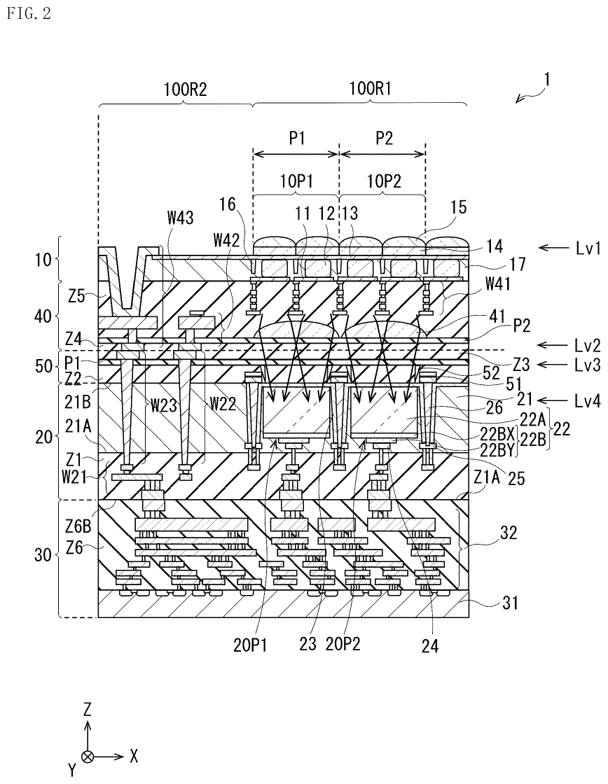

FIG. 2 schematically illustrates an example of a vertical cross-sectional configuration along a thickness direction of a portion of the pixel unit 100. FIG. 2 illustrates, as an example, a pixel P1 and a pixel P2 as some of the plurality of the pixels P arranged in the matrix in the pixel unit 100. In FIG. 2, the thickness direction (stacking direction) of the pixels P1 and P2 is defined as a Z-axis direction. Plane directions parallel to a plane of stacking orthogonal to the Z-axis direction are defined as an X-axis direction and a Y-axis direction. It is to be noted that the X-axis direction, the Y-axis direction, and the Z-axis direction are orthogonal to each other.

As illustrated in FIG. 2, the pixel unit 100 is a so-called imaging element of vertical spectroscopy. That is, the pixel unit 100 has a structure in which a first photodetection unit 10 and a second photodetection unit 20 are stacked in the Z-axis direction, i.e., the thickness direction. The first photodetection unit 10 is configured to detect light in a first wavelength range. The second photodetection unit 20 is configured to detect light in a second wavelength range. Here, the light in the first wavelength range is, for example, visible light, and the light in the second wavelength range is infrared light having a wavelength longer than the wavelength of visible light. The pixel unit 100 further includes an intermediate layer 50, an intermediate layer 40, and a multilayer wiring board 30. The intermediate layer 40 is provided between the first photodetection unit 10 and the second photodetection unit 20 in the Z-axis direction. The intermediate layer 50 is provided between the second photodetection unit 20 and the intermediate layer 40 in the Z-axis direction. The multilayer wiring board 30 is provided on opposite side to the first photodetection unit 10 as viewed from the second photodetection unit 20. Black filters may be provided in the peripheral region 100R2. Furthermore, the second photodetection unit 20 includes, for example, a plurality of color filters 14 and on-chip lenses (OCL) 15 provided in corresponding relation to respective ones of the plurality of the color filters 14. It is to be noted that an antireflection film may be provided to cover the on-chip lenses 15. The plurality of the color filters 14 includes, for example, a color filter that mainly transmits red, a color filter that mainly transmits green, and a color filter that mainly transmits blue. It is to be noted that the pixel P1 of the present embodiment includes each of the red, green, and blue color filters 14, and allow the first photodetection unit 10 to receive each of red light, green light, and blue light to obtain color visible light images.

### <Second Photodetection Unit 20>

<Second Photodetection Unit 20>The second photodetection unit 20 is a direct TOF dTOF) sensor that acquires a distance image (distance information) by, for example, optical time-of-flight (Time-of-Flight; TOF). The second photodetection unit 20 has a stacked structure in which, for example, an insulating layer Z1 and the semiconductor substrate 21 are sequentially stacked in a direction from the multilayer wiring board 30 toward the intermediate layer 50. In the insulating layer Z1, a wiring group W21 is embedded. The insulating layer Z1 includes an inorganic insulating material such as silicon oxide (SiO₂) or aluminum oxide. More specifically, the insulating layer Z1 may include a single-layer film including one of inorganic insulating materials such as silicon oxide (SiOx), silicon nitride (SiNx), and silicon oxynitride (SiON), or a stacked-layer film including two or more of these. Furthermore, as a material constituting the insulating layer Z1, an organic insulating material may be used, e.g., polymethyl methacrylate (PMMA), polyvinyl phenol (PVP), polyvinyl alcohol (PVA), polyimide, polycarbonate (PC), polyethylene terephthalate (PET), polystyrene, N-2(aminoethyl)3-aminopropyltrimethoxysilane (AEAPTMS), 3-mercaptopropyltrimethoxysilane (MPTMS), tetraethoxysilane (TEOS), octadecyltrichlorosilane (OTS), or the like. In the semiconductor substrate 21, a photoelectric conversion region 22, a fixed charge layer 23, a first contact layer 24, a second contact layer 25, and an inter-pixel region light-shielding wall 26 are embedded. However, an upper edge of the inter-pixel region light-shielding wall 26 may protrude from a back surface 21B (described later) of the semiconductor substrate 21 toward the first photodetection unit 10. Examples of a constituent material of the wiring group W21 include highly conductive nonmagnetic materials such as Cu (copper). Moreover, the second photodetection unit 20 includes unit pixel regions 20P (20P1 and 20P2) provided at positions corresponding to respective ones of the plurality of the pixels P.

The semiconductor substrate 21 is, for example, an n-type silicon (Si) substrate including a front surface 21A and the back surface 21B. The semiconductor substrate 21 includes a p-well (p) in a predetermined region. The front surface 21A faces the multilayer wiring board 30. The back surface 21B is a surface facing the intermediate layer 50. The back surface 21B preferably has a fine concavo-convex structure. One reason is because the fine concavo-convex structure is effective in confining infrared light entering the semiconductor substrate 21 inside the semiconductor substrate 21. It is to be noted that the front surface 21A may also have a similar fine concavo-convex structure.

The photoelectric conversion region 22 converts, for example, entering light into an electric signal by photoelectric conversion, and outputs the electric signal. The photoelectric conversion region 22 converts the entering light (photon) into the electric signal by the photoelectric conversion, and outputs a pulse corresponding to the entry of the photon. The photoelectric conversion region 22 is, for example, an SPAD (Single Photon Avalanche Diode) element. For example, the SPAD element has a characteristic in which a large negative voltage is applied to a cathode to generate an avalanche multiplication region (depletion layer), and electrons generated in response to the entry of one photon cause avalanche multiplication, resulting in a large current flow. The photoelectric conversion region 22 detects, in particular, light having a wavelength in an infrared light range, within the light from an object, converts the light into an electric signal, and outputs the electric signal. The photodetector 1 includes the photoelectric conversion region 22 for each unit pixel region 20P.

The photoelectric conversion region 22 includes a light-receiving unit 22A and a multiplying unit 22B. The light-receiving unit 22A has a photoelectric conversion function of absorbing light entering the semiconductor substrate 21 through the back surface 21B and converting photons into electric charge. The light-receiving unit 22A includes, for example, an n-type semiconductor region (n) whose impurity concentration is controlled to be an n-type. The charge (electrons in this case) generated in the light-receiving unit 22A is transferred to the multiplying unit 22B by a potential gradient.

The multiplying unit 22B avalanche-multiplies the charge (electrons) generated in the light-receiving unit 22A. The multiplying unit 22B has, for example, a stacked structure of a p-type semiconductor region (p+) 22BX and an n-type semiconductor region (n+) 22BY. The p-type semiconductor region (p+) 22BX has an impurity concentration higher than that of the p-well (p) of the semiconductor substrate 21. The n-type semiconductor region (n+) 22BY has an impurity concentration higher than that of the n-type semiconductor region (n) of the light-receiving unit 22A. In the photoelectric conversion region 22, an avalanche multiplication region is formed at a junction between the p-type semiconductor region (p+) 22BX and the n-type semiconductor region (n+) 22BY. This avalanche multiplication region is a high electric field region (depletion layer) formed at an interface between the p-type semiconductor region (p+) 22BX and the n-type semiconductor region (n+) 22BY by the large negative voltage applied to the cathode. In this avalanche multiplication region, electrons (e−) generated in the one photon entering the photoelectric conversion region 22 are multiplied.

The fixed charge layer 23 is provided to cover the back surface 21B and the like of the semiconductor substrate 21. The fixed charge layer 23 includes, for example, negative fixed charge, to suppress generation of a dark current caused by an interface level of the back surface 21B as a light-receiving surface of the semiconductor substrate 21. By an electric field induced by the fixed charge layer 23, a hole accumulation layer is formed near the back surface 21B of the semiconductor substrate 21. This hole accumulation layer contributes to suppression of generation of electrons from the back surface 21B. It is to be noted that the fixed charge layer 23 also includes a portion extending in the Z-axis direction between the inter-pixel region light-shielding wall 26 and the photoelectric conversion region 22. The fixed charge layer 23 is preferably formed using an insulating material. Specifically, examples of a constituent material of the fixed charge layer 23 include hafnium oxide (HfOx), aluminum oxide (AlOx), zirconium oxide (ZrOx), tantalum oxide (TaOx), titanium oxide (TiOx), lanthanum oxide (LaOx), praseodymium oxide (PrOx), cerium oxide (CeOx), neodymium oxide (NdOx), promethium oxide (PmOx), samarium oxide (SmOx), europium oxide (EuOx), gadolinium oxide (GdOx), terbium oxide (TbOx), dysprosium oxide (DyOx), holmium oxide (HoOx), thulium oxide (TmOx), ytterbium oxide (YbOx), lutecium oxide (LuOx), yttrium oxide (YOx), hafnium nitride (HfNx), aluminum nitride (AlNx), hafnium oxynitride (HfOxNy), aluminum oxynitride (AlOxNy), and the like.

The first contact layer 24 and the second contact layer 25 are each provided near the front surface 21A of the semiconductor substrate 21. The first contact layer 24 includes an n-type semiconductor region (n++) electrically coupled to the n-type semiconductor region (n+) 22BY constituting the multiplying unit 22B. The second contact layer 25 includes a p-type semiconductor region (p++) electrically coupled to the n-type semiconductor region (n) constituting the light-receiving unit 22A. The second contact layer 25 is provided, as illustrated in, for example, FIG. 2A, to surround the light-receiving unit 22A along the inter-pixel region light-shielding wall 26. To the second contact layer 25, a bias voltage is applied, as an anode of the photoelectric conversion region 22. The first contact layer 24 is the cathode of the photoelectric conversion region 22, and is coupled to, for example, a quenching resistance element.

The inter-pixel region light-shielding wall 26 is provided at a border between the adjacent pixels P in an XY plane. The inter-pixel region light-shielding wall 26 is provided to surround the photoelectric conversion region 22 of each pixel P. By providing the inter-pixel region light-shielding wall 26 at the border between the adjacent pixels P, it is possible to suppress oblique entry of unnecessary light into the photoelectric conversion region 22 of the adjacent pixel P, leading to prevention of color mixing.

The inter-pixel region light-shielding wall 26 includes, for example, a material containing at least one of a metal single substance, a metal alloy, a metal nitride, and a metal silicide that have light-shielding property. More specifically, examples of a constituent material of the inter-pixel region light-shielding wall 26 include Al (aluminum), Cu (copper), Co (cobalt), W (tungsten), Ti (titanium), Ta (tantalum), Ni (nickel), Mo (molybdenum), Cr (chromium), Ir (iridium), platinum iridium, TiN (titanium nitride), and tungsten-silicon compounds. It is to be noted that the constituent material of the inter-pixel region light-shielding wall 26 is not limited to a metal material. The inter-pixel region light-shielding wall 26 may be formed using graphite. Moreover, the inter-pixel region light-shielding wall 26 is not limited to a conductive material, but may include a non-conductive material having the light-shielding property such as an organic material. An insulating layer may be provided outside the inter-pixel region light-shielding wall 26, that is, between the inter-pixel region light-shielding wall 26 and the fixed charge layer 23. Alternatively, a gap may be provided between the inter-pixel region light-shielding wall 26 and the fixed charge layer 23, to provide insulation between the inter-pixel region light-shielding wall 26 and the fixed charge layer 23.

### <Multilayer Wiring Board 30>

The multilayer wiring board 30 is a logic circuit board having a structure in which an insulating layer Z6 is stacked on a semiconductor substrate 31 such as silicon. In the insulating layers Z6, a wiring group 32 constituting a readout circuit is embedded. The readout circuit performs reading out of signal charge from the first photodetection unit 10 and the second photodetection unit 20. Metal terminals of the wiring group 32 exposed in a back surface Z6B of the insulating layer Z6 are directly bonded to metal terminals of a wiring group W21 exposed in a front surface ZIA of the insulating layer Z1 of the second photodetection unit 20. To a constituent material of the insulating layer Z6, for example, the same material as the constituent material of the insulating layer Z1 or the like may be applied. Examples of a constituent material of the wiring group 32 include a highly conductive nonmagnetic material such as Cu (copper).

### <Intermediate Layer 50>

The intermediate layer 50 has a stacked structure in which an insulating layer Z2, a passivation film P1, and an insulating layer Z3 are sequentially stacked in a direction from the second photodetection unit 20 toward the intermediate layer 40. In the insulating layer Z2, a light-shielding layer 51 and an optical waveguide 52 are embedded. To a constituent material of the insulating layers Z2 and Z3, for example, the same material as the constituent material of the insulating layer Z1 is applicable. The passivation film P1 may include an inorganic insulating material such as silicon nitride (Si3N4).

The light-shielding layer 51 is provided at a position superposed with the inter-pixel region light-shielding wall 26 in the Z-axis direction. The light-shielding layer 51 makes it possible to suppress the oblique entry of the unnecessary light into the photoelectric conversion region 22 of the adjacent pixel P, leading to prevention of color mixing. To a constituent material of the light-shielding layer 51, the same constituent material as that of the inter-pixel region light-shielding wall 26 is applicable.

The optical waveguide 52 is a metal waveguide provided at a level between the first photodetection unit 10 and the second photodetection unit 20. The optical waveguide 52 guides the light that has passed through the first photodetection unit 10, toward the photoelectric conversion region 22 of the second photodetection unit 20. The optical waveguide 52 is annularly provided in the XY plane along the outer edge of the photoelectric conversion region 22 of each unit pixel region 20P (20P1 or 20P2). The optical waveguide 52 penetrates the insulating layer Z2 in the Z-axis direction. As is closer to the second photodetection unit 20 from the passivation film P1, for example, a width of the optical waveguide 52 orthogonal to the Z-axis direction becomes gradually narrower. The optical waveguide 52 may include, for example, an Al (aluminum) single substance, or a metal including Al.

The second photodetection unit 20 and the intermediate layer 50 further include a coupling unit W22 and a coupling unit W23. Each of the coupling unit W22 and the coupling unit W23 extends in the Z-axis direction to penetrate the insulating layer Z1, the semiconductor substrate 21, the insulating layer Z2, the passivation film P1, and the insulating layer Z3, from the wiring group W21 provided in the insulating layer ZI to a back surface of the insulating layer Z3 facing the intermediate layer 40.

### <Intermediate Layer 40>

The intermediate layer 40 has a stacked structure in which, for example, an insulating layer Z4, a passivation film P2, and an insulating layer Z5 are sequentially stacked in a direction from the intermediate layer 50 toward the first photodetection unit 10. In the insulating layer Z5, condenser lenses 41 and wiring groups W41, W42, and W43 are embedded. To a constituent material of the insulating layers Z4 and Z5, for example, the same material as the constituent material of the insulating layer Z1 or the like may be applied. For example, the one condenser lens 41 is provided for each pixel P. The condenser lenses 41 include, for example, a resin material configured to transmit the light in the second wavelength range (for example, infrared light) that has passed through the first photodetection unit 10. The condenser lenses 41 are optical elements that condense the light in the second wavelength range (for example, infrared light) that has passed through the first photodetection unit 10 and guide the condensed light to the second photodetection unit 20. That is, the condenser lenses 41 are positive lenses having positive refractive power with respect to the light in the second wavelength range. It is to be noted that the condenser lenses 41 may also have positive refractive power with respect to the light in the first wavelength range (for example, visible light).

The wiring group W41 is coupled to a lower electrode 11 of the first photodetection unit 10 described later. The wiring group W41 is coupled to a part of the wiring group W42. At an interface between the intermediate layer 40 and the intermediate layer 50, the wiring group W42 is coupled to the coupling unit W22. The wiring group W43 is coupled to an upper electrode 13 of the first photodetection unit 10 described later. The wiring group W43 is coupled to the coupling unit W23 at the interface between the intermediate layer 40 and the intermediate layer 50.

At least one of the intermediate layer 40 and the intermediate layer 50 may further include a predetermined optical filter. The optical filter has a transmission band in the second wavelength range in which the photoelectric conversion is performed in the photoelectric conversion region 22. That is, the optical filter is easier to transmit light having a wavelength in the second wavelength range than light having a wavelength in the first wavelength range. Specifically, the optical filter may include, for example, an organic material, and absorbs at least a part of light having a wavelength in the visible light range while selectively transmitting light in the infrared light range. The optical filter includes an organic material such as a phthalocyanine derivative.

### <First Photodetection Unit 10>

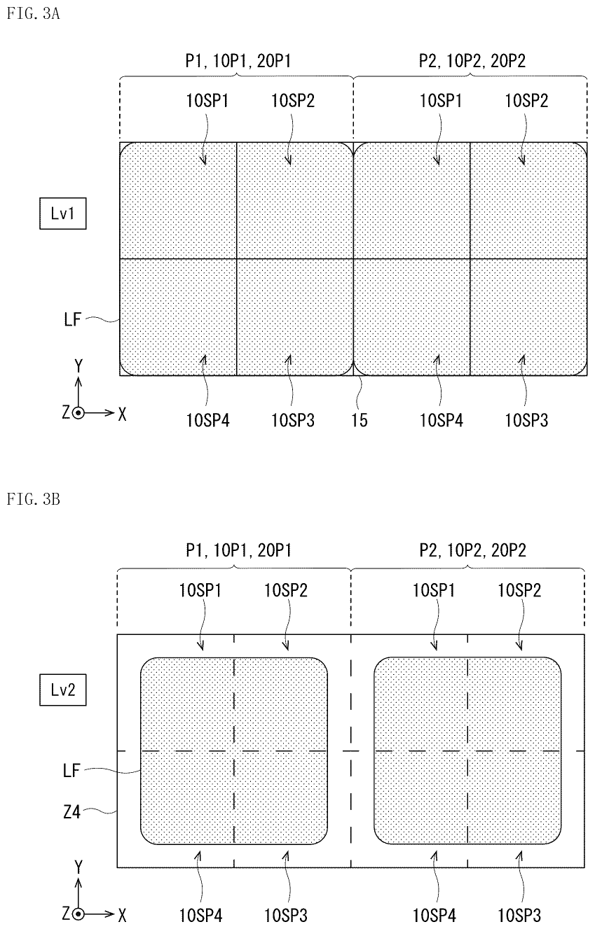

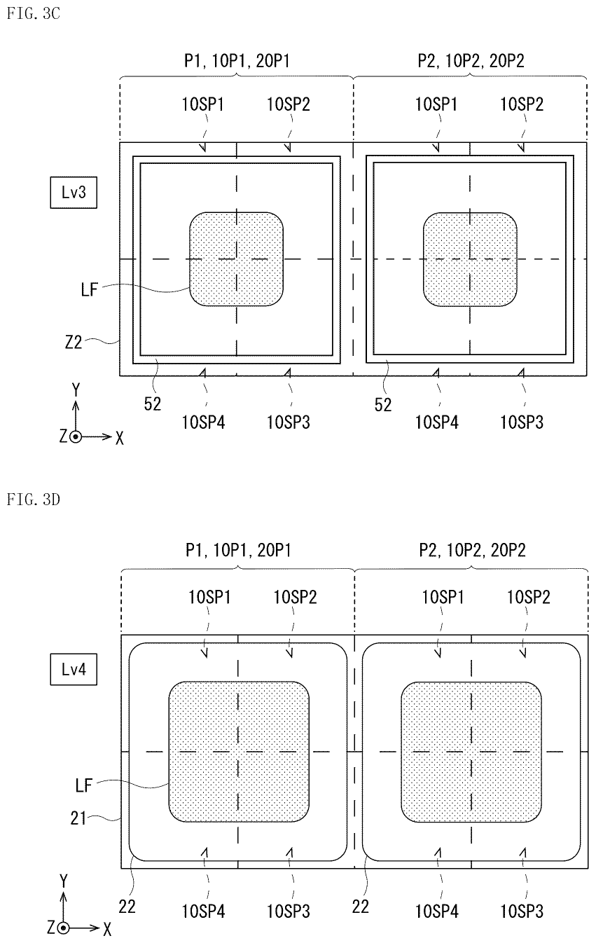

The first photodetection unit 10 includes unit pixel regions 10P (10P1 and 10P2) provided at positions corresponding to respective ones of the plurality of the pixels P. Each of the unit pixel regions 10P (10P1 and 10P2) includes a plurality of sub-pixel regions 10SP. In the present embodiment, as illustrated in FIG. 3A, the unit pixel regions 10P (10P1 and 10P2) each include four sub-pixel regions 10SP1 to 10SP4. FIG. 3A schematically illustrates a configuration example of a horizontal cross-section of the pixel P along the XY plane orthogonal to the Z-axis direction, at a height level Lv1 in the Z-axis direction illustrated in FIG. 2. That is, FIG. 3A illustrates a configuration example of a horizontal cross-section including the OCLs 15. It is to be noted that, in FIG. 3A, reference characters LF indicate spread of a light flux of light from the outside that has entered the OCLs 15.

The first photodetection unit 10 includes, for each sub-pixel region 10SP, the lower electrode 11, a photoelectric conversion region 12, the upper electrode 13, the color filter 14, and the OCL 15 that are sequentially stacked from, for example, a position close to the second photodetection unit 20. Between the sub-pixel regions 10SP, an inter-pixel light-shielding unit 16 is provided. The inter-pixel light-shielding unit 16 shields the light in the first wavelength range. The lower electrode 11, the photoelectric conversion region 12, and the upper electrode 13 are embedded in a semiconductor substrate 17.

The lower electrode 11 and the upper electrode 13 include a light-transmitting conductive film. For example, the lower electrode 11 and the upper electrode 13 include ITO (indium tin oxide). However, as a constituent material of the lower electrode 11 and the upper electrode 13, in addition to ITO, a tin oxide (SnOx)-based material to which a dopant is added, or a zinc oxide-based material obtained by adding a dopant to a zinc oxide (ZnO) may be used. Examples of the zinc oxide-based material include aluminum zinc oxide (AZO) to which aluminum (Al) is added as a dopant, gallium zinc oxide (GZO) to which gallium (Ga) is added, and indium zinc oxide (IZO) to which indium (In) is added. Moreover, as the constituent material of the lower electrode 11 and the upper electrode 13, CuI, InSbO₄, ZnMgO, CuInO₂, MgIN₂O₄, CdO, ZnSnO₃, TiO₂, or the like may be used. Furthermore, a spinel-type oxide or an oxide having a YbFe₂O₄ structure may be used.

The photoelectric conversion region 12 converts light energy into electric energy. The photoelectric conversion region 12 includes, for example, two or more kinds of organic materials that serve as a p-type semiconductor and an n-type semiconductor. The p-type semiconductor relatively serves as an electron donor, and the n-type semiconductor serves as an n-type semiconductor that relatively serves as an electron acceptor. The photoelectric conversion region 12 has a bulk heterojunction structure in the layer. The bulk heterojunction structure is a p/n junction interface formed by the p-type semiconductor and the n-type semiconductor mixed together. Excitons generated when absorbing light separates into electrons and holes at the p/n junction interface.

In addition to the p-type semiconductor and the n-type semiconductor, the photoelectric conversion region 12 may further include three kinds of so-called dye materials that perform photoelectric conversion of light in a predetermined wavelength band while transmitting light in other wavelength bands. The p-type semiconductor, the n-type semiconductor, and the dye materials preferably have absorption maximum wavelengths different from each other. This makes it possible to absorb a wide range of wavelengths in the visible light range.

The photoelectric conversion region 12 can be formed by, for example, mixing the various kinds of the organic semiconductor materials described above and using a spin coating technique. In addition, for example, the photoelectric conversion region 12 may be formed using a vacuum deposition method, a printing technique, or the like.

The photoelectric conversion region 12 detects a part or all of the light in the first wavelength range. Moreover, it is desirable that the photoelectric conversion region 12 be devoid of sensitivity to the light in the second wavelength range.

Light entering on side on which the upper electrode 13 is disposed is absorbed by the photoelectric conversion region 12. The excitons (electron-hole pairs) thus generated move to the interface between the electron donor and the electron acceptor constituting the photoelectric conversion region 12, and cause exciton separation, or dissociate into electrons and holes. The charge generated here, i.e., the electrons and the holes, is transferred to the upper electrode 13 or the lower electrode 11 by diffusion due to a difference in a carrier concentration or an internal electric field due to a potential difference between the upper electrode 13 and the lower electrode 11, and is detected as a photocurrent.

### <1-2. Workings and Effects>

The photodetector 1 of the present embodiment includes the first photodetection unit 10 and the second photodetection unit 20. The first photodetection unit 10 is configured to detect the light in the first wavelength range. The second photodetection unit 20 is stacked with the first photodetection unit 10 and configured to detect the light in the second wavelength range different from the light in the first wavelength range. The photodetector 1 further includes the condenser lenses 41 as the optical elements between the first photodetection unit 10 and the second photodetection unit 20. The condenser lenses 41 converge the light in the second wavelength range that has passed through the first photodetection unit 10 and guide the condensed light to the second photodetection unit 20. As described, because the condenser lenses 41 are disposed at the predetermined positions, in the photodetector 1, the light in the first wavelength range that has passed through the first photodetection unit 10 of a certain pixel P enters the second photodetection unit 20 which the light originally ought to enter, without leaking out to the second photodetection unit 20 of another pixel P nearby. Hence, it is possible to prevent the decline in the detection sensitivity, and suppress the occurrence of so-called crosstalk.

Thus, according to the photodetector 1 of the present embodiment, by stacking the first photodetection unit 10 and the second photodetection unit 20, it is possible to realize high integration in the XY plane, and enhance the resolution. In addition, it is possible for the photodetector 1 of the present embodiment to exhibit even better photodetection performance.

Here, referring to FIGS. 3B to 3D in addition to FIGS. 2 and 3A, the behavior of the light entering the photodetector 1 is described. FIGS. 3B to 3D schematically illustrate configuration examples of horizontal cross-sections of the pixel P at the respective height levels Lv2 to Lv4 of the photodetector 1 illustrated in FIG. 2. FIG. 3B illustrates the horizontal cross-section of the insulating layer Z4 of the intermediate layer 40. FIG. 3C illustrates the horizontal cross-section of the insulating layer Z2 of the intermediate layer 50. Furthermore, FIG. 3D illustrates the horizontal cross-section of the semiconductor substrate 21 in which the photoelectric conversion region 22 is provided.

As illustrated in FIG. 3A, the luminous flux entering the OCLs 15 spreads over almost the entirety of the pixel P1. Within the light entering the OCLs 15, the light in the first wavelength range is subjected to the photoelectric conversion when passing through the first photodetection unit 10 provided for each sub-pixel region 10SP. Thereafter, the light that has passed through the first photodetection unit 10 enters the intermediate layer 40 and is condensed by the condenser lenses 41. Thus, as illustrated in FIG. 3B, occupied area of the light flux LF in the horizontal cross-section at the height level Lv2 is smaller than the occupied area of the light flux LF in the horizontal cross-section at the height level Lv1. As the light travels further, as illustrated in FIG. 3C, the occupied area of the light flux LF in the horizontal cross-section at the height level Lv3 becomes even smaller than the occupied area of the light flux LF in the horizontal cross-section at the height level Lv2. In the horizontal cross-section at the height level Lv3, the occupied area of the light flux LF is sufficiently smaller than area of an opening in the optical waveguide 52. Thereafter, when the light travels from the height level Lv3 to the height level Lv4, the thickness of the light flux LF becomes slightly larger, causing the occupied area of the light flux LF in the horizontal cross-section at the height level Lv4 to become larger than the occupied area of the light flux LF in the horizontal cross-section at the height level Lv3. Nevertheless, it is possible to keep the occupied area of the light flux LF in the horizontal cross-section at the height level Lv4 sufficiently smaller than occupied area of the photoelectric conversion region 22 in the horizontal cross-section at the same height level Lv4. Hence, it is possible to prevent the light that has passed through the first photodetection unit 10 of the pixel P from unintentionally entering the second photodetection unit 20 of another pixel P nearby.

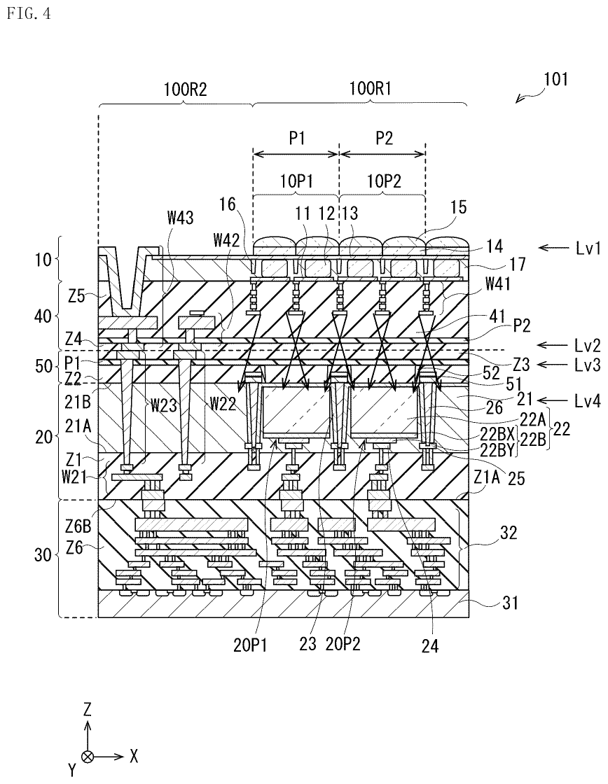

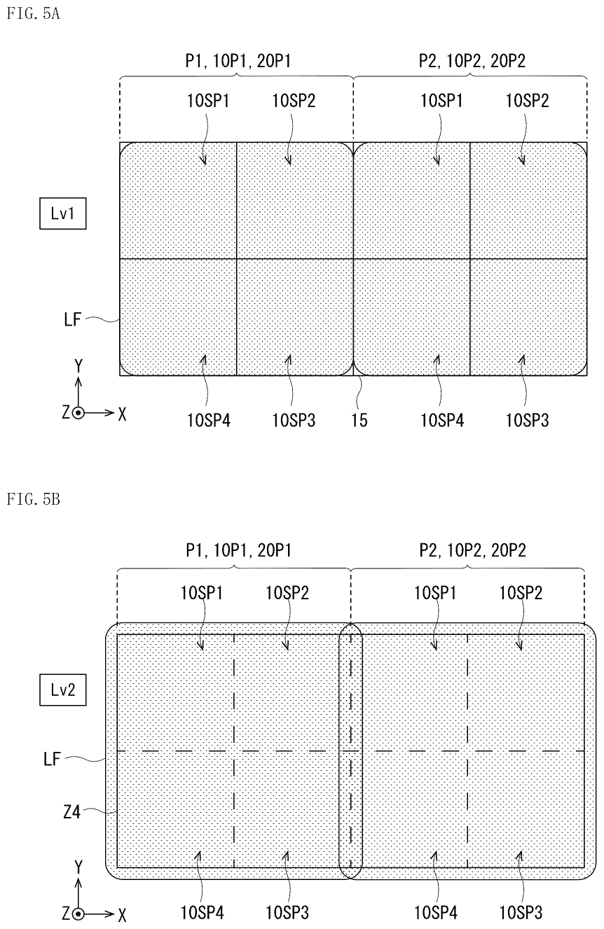

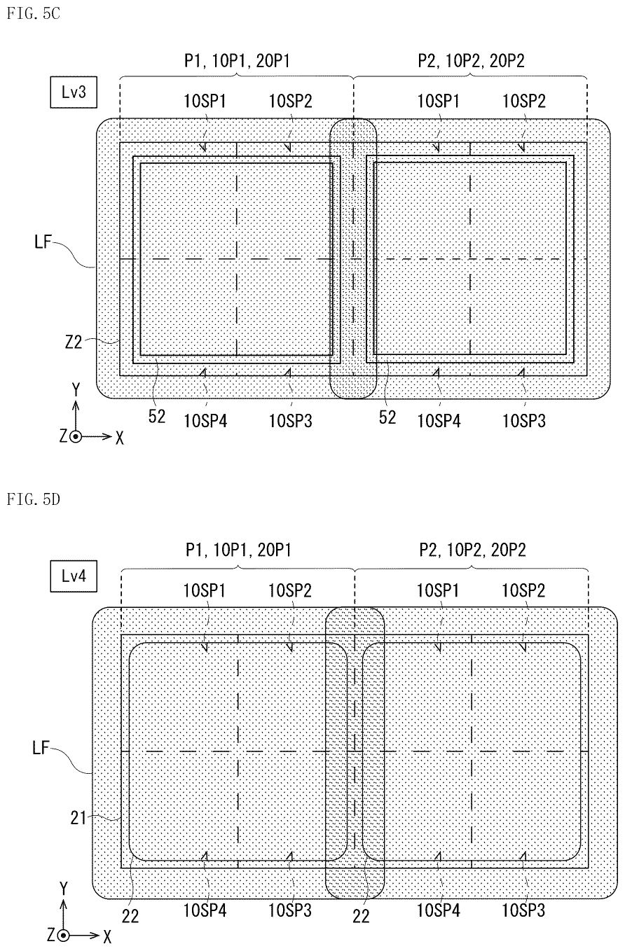

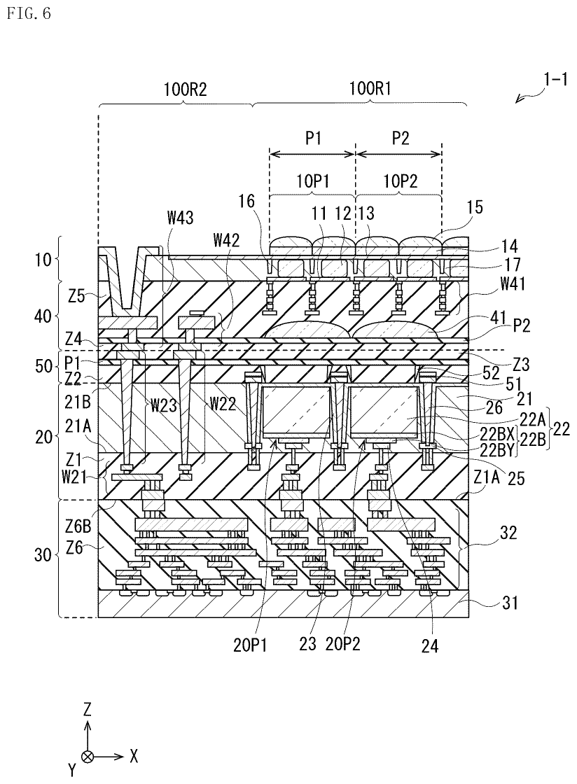

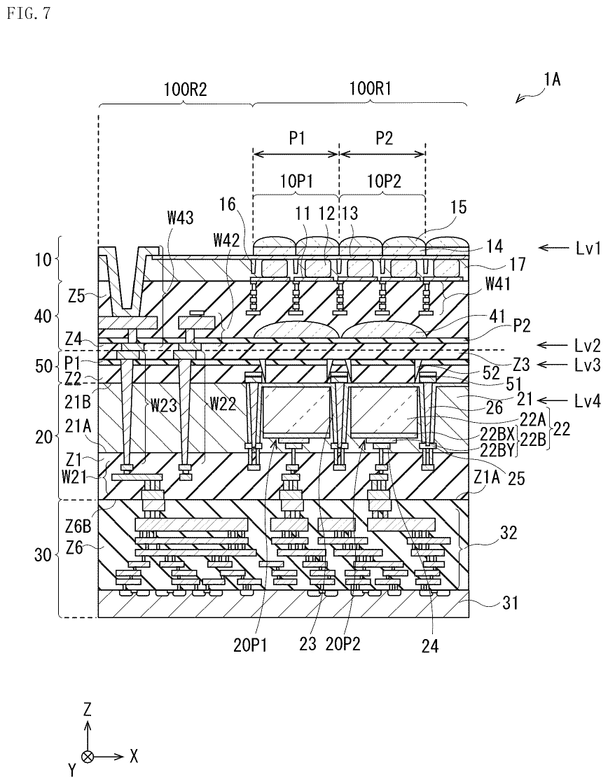

However, as in a photodetector 101 as a reference example illustrated in FIG. 4, when no optical elements having a condensing effect such as the condenser lenses 41 are provided between the first photodetection unit 10 and the second photodetection unit 20, a beam spot of light entering the photodetector 101 gradually enlarges, as advances in the Z-axis direction. The photodetector 101 has the same configuration as that of the photodetector 1 except that the photodetector 101 is devoid of the condenser lenses 41. FIGS. 5A to 5D schematically illustrate configuration examples of horizontal cross-sections of the pixel P at the respective height levels Lv1 to Lv4 of the photodetector 101 illustrated in FIG. 4. As illustrated in FIG. 5A, a luminous flux entering the OCLs 15 spreads over almost the entirety of the pixel P1. The light entering the OCLs 15 passes through the first photodetection unit 10, and thereafter, enters the intermediate layer 40. However, because of the absence of the condenser lenses, the light diffuses as it travels in the Z-axis direction. Accordingly, as illustrated in FIG. 5B, the occupied area of the light flux LF in the horizontal cross-section at the height level Lv2 is larger than the occupied area of the light flux LF in the horizontal cross-section at the height level Lv1. As the light travels further, as illustrated in FIG. 5C, the occupied area of the light flux LF in the horizontal cross-section at the height level Lv3 becomes even larger smaller than the occupied area of the light flux LF in the horizontal cross-section at the height level Lv2. In the horizontal cross-section at the height level Lv3, the occupied area of the light flux LF is even larger than the area of the opening in the optical waveguide 52. Thereafter, when the light travels from the height level Lv3 to the height level Lv4, the thickness of the light flux LF becomes even larger, causing the occupied area of the light flux LF in the horizontal cross-section at the height level Lv4 to become even larger than the occupied area of the light flux LF in the horizontal cross-section at the height level Lv3. Thus, the occupied area of the light flux LF in the horizontal cross-section at the height level Lv4 ends up in being larger than the occupied area of the photoelectric conversion region 12 in the horizontal cross-section at the same height level Lv4. Accordingly, the light that has passed through the first photodetection unit 10 of the pixel P ends up in unintentionally entering the second photodetection unit 20 of another pixel P nearby.

In contrast, in the photodetector 1 of the present embodiment, the light that has passed through the first photodetection unit 10 of one pixel P is condensed by the condenser lens 41. Accordingly, it is possible to deliver the light to the second photodetection unit 20 of the pixel P without allowing the light to enter the second photodetection unit 20 of another pixel P. This leads to the entry of a sufficient amount of the light in the second wavelength range into the unit pixel region 10P of each pixel, while avoiding the entry of unnecessary light into the unit pixel region 10P of each pixel P.

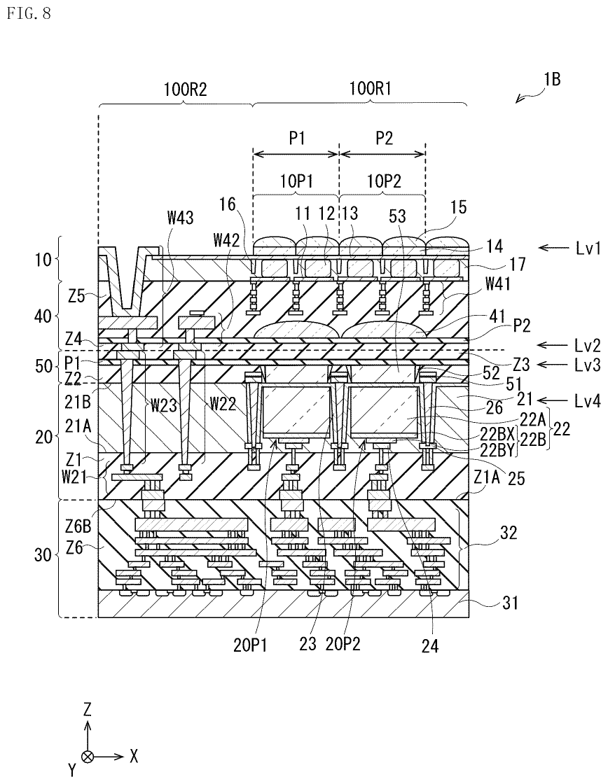

Hence, it is possible to avoid the occurrence of so-called crosstalk even when the center positions of the unit pixel regions 10P (10P1 and 10P2) deviate, in the XY-plane direction, from the center positions of the unit pixel regions 20P (20P1 and 20P2) corresponding thereto, due to manufacturing errors or the like, as in a photodetector 1-1 illustrated in, for example, FIG. 6.

Furthermore, in the photodetector 1 of the present embodiment, the optical waveguide 52 is provided in the intermediate layer 50 along the outer edge of the second photodetection unit 20. Hence, it is possible to guide the light that unintentionally heads for the adjacent pixel P due to unintended reflection or the like, toward the second photodetection unit 20 which the light originally ought to enter. This leads to further reduction in the occurrence of crosstalk.

### <1-3. Modification Example>

### <Modification Example 1-1>

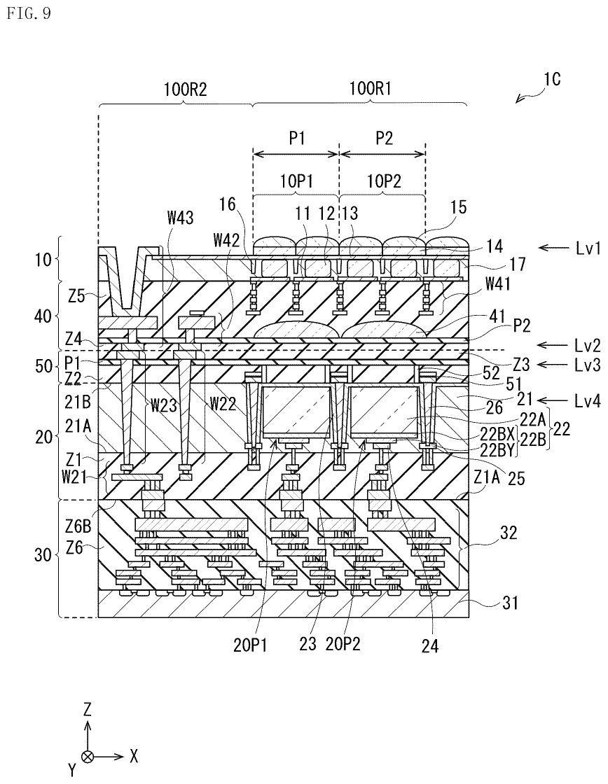

FIG. 7 is a cross-sectional view illustrating a configuration example of a vertical cross-section of a photodetector 1A as a first modification example of the forgoing first embodiment. In the photodetector 1 of the forgoing first embodiment, the optical waveguide 52 penetrates the insulating layers Z2 in the Z-axis direction. In contrast, in the photodetector 1A in FIG. 7, the optical waveguide 52 not only penetrates the insulating layer Z2 but also penetrates the passivation film P1 provided on the insulating layer Z2. Otherwise, the configuration of the photodetector 1A is substantially the same as the configuration of the photodetector 1. In the photodetector 1A having such a configuration, it is possible to more effectively prevent the light that ought to enter the first photodetection unit 10 of the predetermined pixel P from entering the second photodetection unit 20 of another pixel P.

### <Modification Example 1-2>

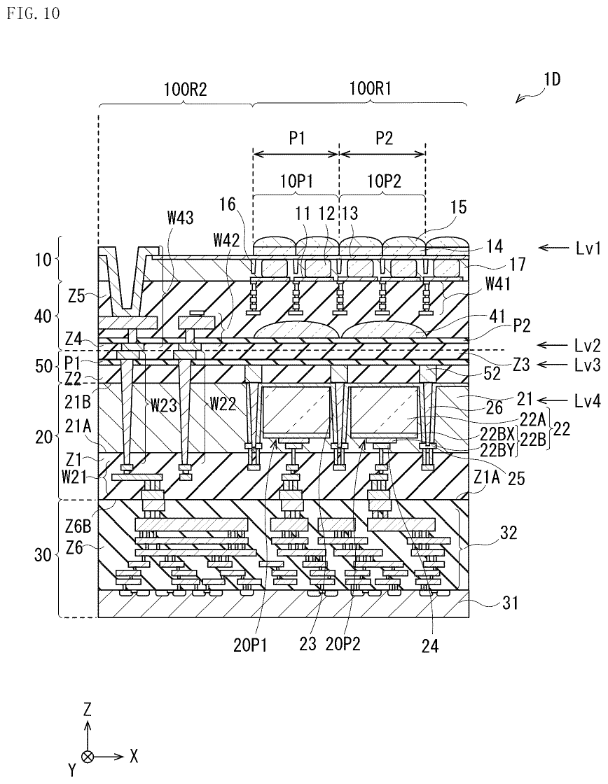

FIG. 8 is a cross-sectional view illustrating a configuration example of a vertical cross-section of a photodetector 1B as a second modification example of the forgoing first embodiment. In the photodetector 1B in FIG. 8, a portion of the insulating layer Z2 surrounded by the optical waveguide 52 along the XY plane is replaced with a high-refractive index material 53. The high refractive index material 53 has, for example, a refractive index higher than a refractive index of the insulating layers Z2 and a refractive index of the passivation film P1 with respect to the light in the second wavelength range. Otherwise, the configuration of the photodetector 1B is substantially the same as the configuration of the photodetector 1. In the photodetector 1B having such a configuration, because the high refractive index material 53 is provided, a physical wavelength of light passing through the high refractive index material 53 is shortened. This hinders the light that has passed through the first photodetection unit 10 from spreading over the periphery, making it possible to more efficiently deliver the light in the second wavelength range to the second photodetection unit 20.

### <Modification Example 1-3>

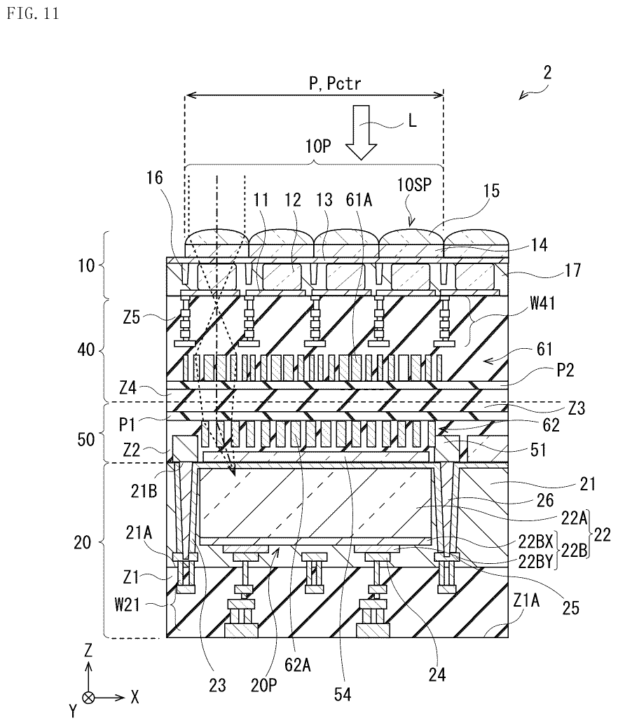

FIG. 9 is a cross-sectional view illustrating a configuration example of a vertical cross-section of a photodetector 1C as a third modification example of the forgoing first embodiment. In the photodetector 1 of the first embodiment, as is closer to the second photodetection unit 20 from the passivation film P1 along the optical waveguide 52 in the Z-axis direction, the width of the optical waveguide 52 orthogonal to the Z-axis direction is gradually narrowed. In contrast, in the photodetector 1C in FIG. 9, the width of the optical waveguide 52 orthogonal to the Z-axis direction is substantially constant. Otherwise, the configuration of the photodetector 1B is substantially the same as the configuration of the photodetector 1. It is to be noted that the optical waveguide 52 may be electrically coupled to the light-shielding layer 51 and the inter-pixel region light-shielding wall 26, and may have the same potential as that of the second contact layer 25 as the anode.

### <Modification Example 1-4>

FIG. 10 is a cross-sectional view illustrating a configuration example of a vertical cross-section of a photodetector 1D as a fourth modification example of the forgoing first embodiment. In the photodetector 1D in FIG. 10, the optical waveguide 52 is also provided at a position superposed with the inter-pixel region light-shielding wall 26 in the Z-axis direction. That is, the light-shielding layer 51 is replaced with the optical waveguide 52. Otherwise, the configuration of the photodetector 1D is substantially the same as the configuration of the photodetector 1. The photodetector 1D is simplified in terms of the configuration, as compared with the photodetector 1.

### 2. Second Embodiment

### <2-1. Configuration>

FIG. 11 schematically illustrates an example of a cross-sectional configuration of a photodetector 2 according to a second embodiment of the present disclosure. In the photodetector 1 according to the forgoing first embodiment, the light from the first photodetection unit 10 is condensed using the condenser lenses 41 and the condensed light is guided to the second photodetection unit 20. In contrast, the photodetector 2 of the present embodiment includes metalenses 61 and 62 using metasurface technology instead of the condenser lenses 41. Moreover, the photodetector 2 includes an optical filter 54 embedded in the insulating layer Z2 of the intermediate layer 50. Furthermore, in the photodetector 2, the unit pixel region 10P corresponding to one pixel P includes sixteen sub-pixel regions 10SP in total in a four-by-four array in both the X-axis direction and the Y-axis direction. Otherwise, the configuration of the photodetector 2 is substantially the same as the configuration of the photodetector 1. It is to be noted that FIG. 11 illustrates only one pixel P (in particular, the pixel Pctr near the center) of the effective region 100R1 within the pixel unit 100 of the photodetector 2, to make it easier to see the structure of the metalens 61, and the illustration of the peripheral region 100R2 is omitted. Furthermore, in FIG. 11, the illustration of the multilayer wiring board 30 is omitted.

As illustrated in FIG. 11, in the photodetector 2, the metalens 61 is provided as the optical element. The metalens 61 is embedded in the insulating layer Z5 of the intermediate layer 40. The metalens 61 has a plurality of structural bodies 61A of a size equal to or smaller than the wavelength of the light in the second wavelength range (for example, infrared light) to be detected by the second photodetection unit 20. Specifically, each of the plurality of the structural bodies 61A has a width and a height equal to or smaller than the wavelength of the light in the second wavelength range. As used here, the width refers to a dimension in the XY-plane direction orthogonal to the Z-axis, and the height as used here refers to a length in the Z-axis direction. The plurality of the structural bodies 61A is regularly distributed over substantially the entirety of each unit pixel region 10P. The plurality of the structural bodies 61A is dielectric waveguides including a dielectric material such as, for example, silicon oxide (SiOx).

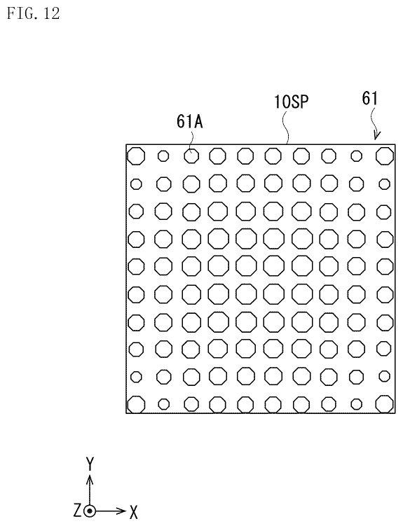

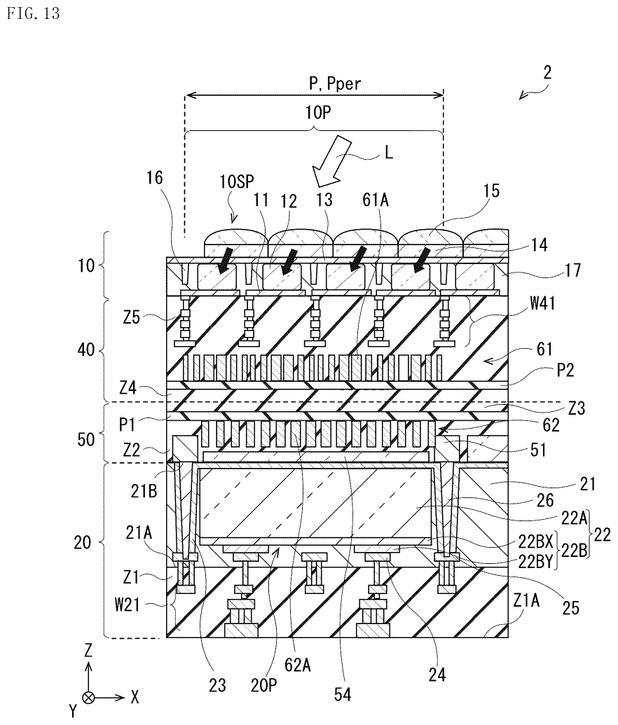

FIG. 12 is a schematic diagram illustrating shapes, sizes, and arrangement positions of the plurality of the structural bodies 61A in the XY plane in a portion of the metalens 61 corresponding to each sub-pixel region 10SP. As illustrated in FIG. 12, the plurality of the structural bodies 61A is regularly arranged at substantially constant pitches with respect to each other in the XY-plane direction orthogonal to a direction in which the first photodetection unit 10 and the second photodetection unit 20 are superposed (Z-axis direction). The plurality of the structural bodies 61A has, for example, the maximum thickness near the center of each sub-pixel region 10SP, and becomes gradually thinner as goes toward a peripheral region of each sub-pixel region 10SP.

In the photodetector 2, as the optical element, the metalens 62 is also provided in the intermediate layer 50. The metalens 62 is embedded in the insulating layer Z2. That is, in the photodetector 2, the metalens 61 and the metalens 62 as the plurality of the optical elements are stacked with each other. As with the metalens 61, the metalens 62 has a plurality of structural bodies 62A of a size equal to or smaller than the wavelength of the light in the second wavelength range (for example, infrared light) to be detected by the second photodetection unit 20. Specifically, each of the plurality of the structural bodies 62A has a width and a height equal to or smaller than the wavelength of the light in the second wavelength range. However, the arrangement positions, dimensions, and shapes of the plurality of the structural bodies 61A are not limited to those illustrated in FIGS. 11 and 12, but any design may be possible.

The plurality of the structural bodies 62A is regularly distributed over substantially the entirety of each unit pixel region 20P. The plurality of the structural bodies 62A has, for example, the maximum thickness near the center of each unit pixel region 20P, and becomes gradually thinner as goes toward a peripheral region of each sub-pixel region 20SP. However, the arrangement positions, dimensions, and shapes of the plurality of the structural bodies 62A are not limited to those illustrated in FIG. 11, but any design may be possible.

The optical filter 54 embedded in the insulating layer Z2 of the intermediate layer 50 suppresses transmission of the light in the first wavelength range (for example, visible light) and selectively transmits the light in the second wavelength range (for example, infrared light).

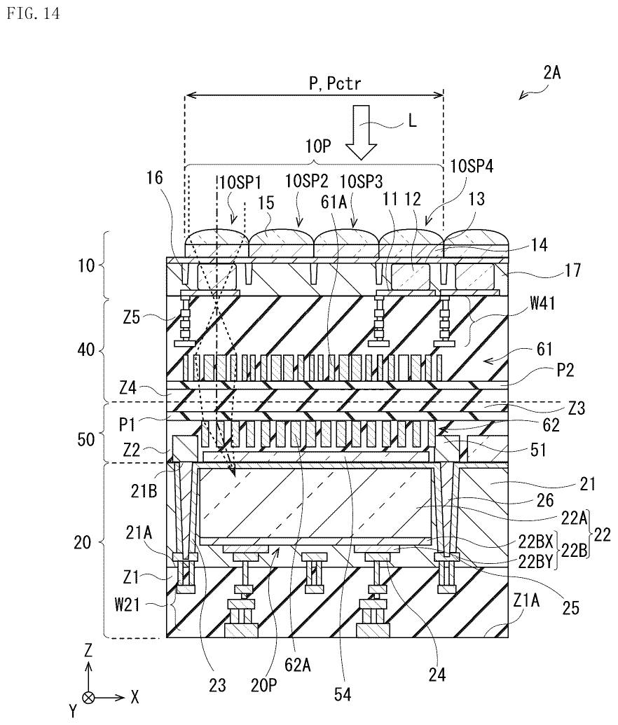

Further, FIG. 11 illustrates a configuration example of a vertical cross-section of a pixel Pctr near the center of the effective region 100R1 of the pixel unit 100. Meanwhile, FIG. 13 illustrates a configuration example of a vertical cross-section of a pixel Pper in a peripheral region of the effective region 100R1 of the pixel unit 100 of the photodetector 2. As illustrated in FIG. 11, light L from an object enters the pixel Pctr near the center of the effective region 100R1 substantially parallel to the Z-axis direction, that is, perpendicularly to the XY plane as the light-receiving surface. Meanwhile, the light L from the object enters the pixel Pper illustrated in FIG. 13 in a direction inclined with respect to the Z-axis direction. That is, the light L obliquely enters the XY surface as the light-receiving surface.

Accordingly, in the pixel Pper, the positions of the color filters 14 and the OCLs 15 in the XY-plane direction are deviated, in accordance with an assumed inclination angle of the light L, from the position of the photoelectric conversion region 12 corresponding to the color filters 14 and the OCLs 15 in the XY-plane direction. In this way, the light that has entered the OCL 15 of a certain sub-pixel region 10SP enters the photoelectric conversion region 12 of the sub-pixel region 10SP through the color filter 14 of the sub-pixel region 10SP. Within the light entering the photoelectric conversion region 12, a component of the light in the first wavelength range is subjected to the photoelectrical conversion, and a component of the light in the second wavelength range is transmitted. The light in the second wavelength range that has passed through the photoelectric conversion region 12 is deflected toward the vertical direction while being condensed by the metalens 61, and thereafter, the deflected light is condensed by the metalens 62 and enters the photoelectric conversion region 22 of the second photodetection unit

### <2-2. Workings and Effects>

As described above, in the photodetector 2 of the present embodiment, the metalens 61 and the metalens 62 as the optical elements are provided between the first photodetection unit 10 and the second photodetection unit 20. The metalenses 61 and 62 condense the light in the second wavelength range that has passed through the first photodetection unit 10 and guide the condensed light to the second photodetection unit 20. Accordingly, in the photodetector 2, the light in the first wavelength range that has passed through the first photodetection unit 10 of a certain pixel P enters the second photodetection unit 20 which the light originally ought to enter, without leaking out to the second photodetection unit 20 of another pixel P nearby. Hence, according to the photodetector 2, it is possible to expect similar effects to the photodetector of the forgoing first embodiment.

### <2-3. Modification Example>

### <Modification Example 2-1>

FIG. 14 is a cross-sectional view illustrating a configuration example of a vertical cross-section of a photodetector 2A as a first modification example of the forgoing second embodiment. In the photodetector 2 of the forgoing second embodiment, the photoelectric conversion region 12 and the like are provided in an entire region corresponding to one pixel P. In contrast, in the photodetector 2A in FIG. 14, sub-pixel regions 10SP2 and 10SP3 are present in a portion of the region corresponding to one pixel P. The sub-pixel regions 10SP2 and 10SP3 are devoid of the lower electrode 11 and the photoelectric conversion region 12. Accordingly, in the sub-pixel regions 10SP2 and 10SP3 devoid of the lower electrode 11 and the photoelectric conversion region 12, the visible light within the light L from the object enters, as it is, the second photodetection unit 20 through the metalenses 61 and 62, the optical filter 54, and the like, without being subjected to the photoelectric conversion. Such sub-pixel regions 10SP2 and 10SP3 devoid of the photoelectric conversion region 12 and the like is used for, for example, pupil correction.

### 3. Application Examples

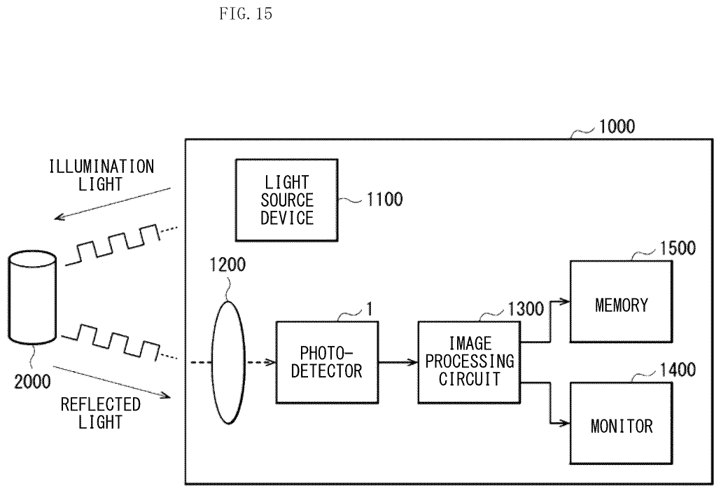

FIG. 15 illustrates an example of a schematic configuration of a distance image device 1000 as an electronic device including the photodetector of the present disclosure (for example, the photodetector 1). The distance image device 1000 is a specific example serving as a “ranging device” of the present disclosure.

The distance image device 1000 includes, for example, a light source device 1100, an optical system 1200, the photodetector 1, an image processing circuit 1300, a monitor 1400, and a memory 1500.

The distance image device 1000 is configured to acquire a distance image in accordance with a distance to an object of illumination 2000 by receiving light (modulated light or pulsed light) projected from the light source device 1100 toward the object of illumination 2000 and reflected from a surface of the object of illumination 2000.

The optical system 1200 includes one or a plurality of lenses. The optical system 1200 guides image light (entering light) from the object of illumination 2000 to the photodetector 1, to form an image on the light-receiving surface (sensor unit) of the photodetector 1.

The image processing circuit 1300 performs image processing to construct the distance image based on a distance signal supplied from the photodetector 1. The distance image (image data) obtained by the image processing is supplied to the monitor 1400 and displayed, or is supplied to the memory 1500 and stored (recorded).

In the distance image device 1000 thus configured, applying the photodetector described above (for example, the photodetector 1) makes it possible to calculate the distance to the object of illumination 2000 based on only a light-receiving signal from the unit pixel P having high stability, and to generate a highly accurate distance image. That is, it is possible for the distance image device 1000 to acquire a more accurate distance image.

### 4. Applied Examples

<Applied Examples to Mobile Body>The technology according to the present disclosure is applicable to various products. For example, the technique according to the present disclosure may be achieved as a device mounted on any kind of mobile body such as an automobile, an electric vehicle, a hybrid electric vehicle, a motorcycle, a bicycle, a personal mobility, an aircraft, a drone, a vessel, a robot, construction machinery, and agricultural machinery (tractor).

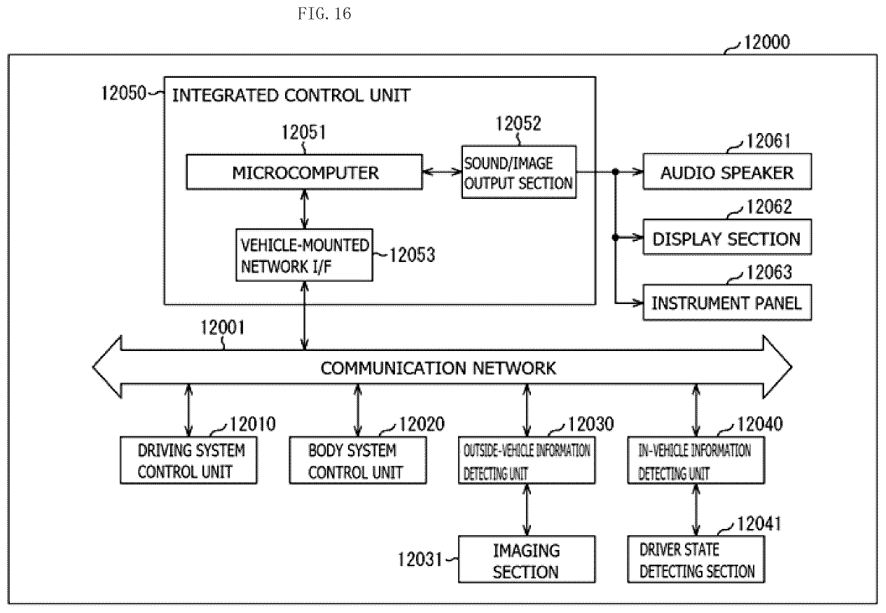

FIG. 16 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 16, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 16, an audio speaker 12061, a display section 12062, and an instrument panel 12063 are illustrated as the output device. The display section 12062 may, for example, include at least one of an on-board display and a head-up display.

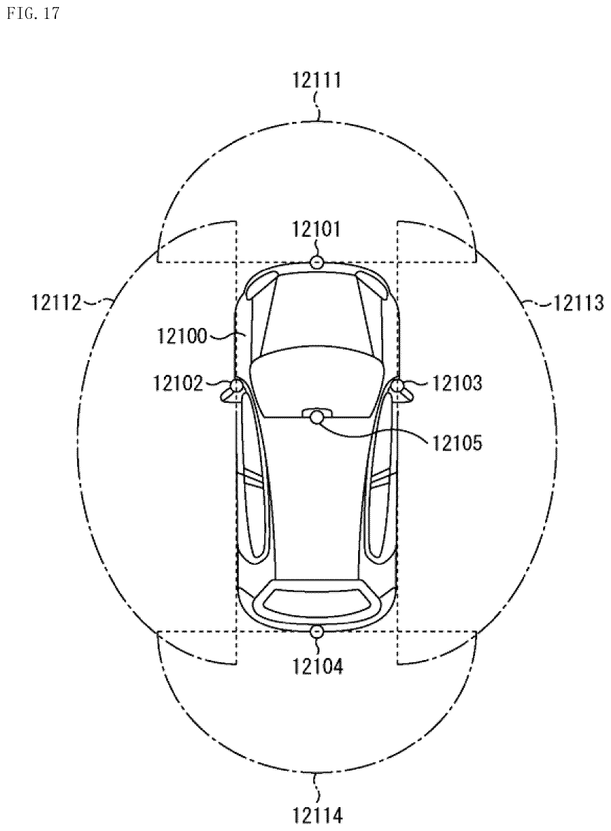

FIG. 17 is a diagram depicting an example of the installation position of the imaging section 12031.

In FIG. 36, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 17 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for Example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Although some embodiments and modification examples, and application examples and applied examples have been described in the forgoing, the contents of the present disclosure are by no means limited to the forgoing embodiments and the like, and various modifications may be made. For example, the photodetector according to the present disclosure does not have to include all the constituent elements described in the forgoing embodiments and the like. Moreover, conversely the photodetector according to the present disclosure may include other layers.

For example, in the first embodiment and the second embodiment, the case where the first photodetection unit detects visible light and the second photodetection unit detects infrared light is given as an example, but the present disclosure is not limited thereto. The wavelength ranges of the light to be detected by the first photodetection unit and the second photodetection unit may be set to any values.

In addition, in the first embodiment and the second embodiment, the description is made by giving the example where the second photodetection unit includes the SPAD element. However, the present disclosure is not limited thereto. The second photodetection unit may include a photoelectric conversion element including, for example, a PIN (Positive Intrinsic Negative) photodiode (PD).

Furthermore, in the photodetector according to the present disclosure, an indirect TOF (iTOF) sensor may be employed as the second photodetection unit.

Moreover, in the first embodiment and the second embodiment described above, the case where the first photodetection unit includes the photoelectric conversion region including an organic semiconductor material is given as an example. However, the present disclosure is not limited thereto. The first photodetection unit may include a photoelectric conversion region including, for example, an inorganic semiconductor material such as Si (silicon).

In the photodetector according to an embodiment of the present disclosure, between the first photodetection unit and the second photodetection unit, one or the plurality of the optical elements is provided. The one or the plurality of the optical elements converges the light in the second wavelength range that has passed through the first photodetection unit, and guides the condensed light to the second photodetection unit. Hence, it is possible for the photodetector of the present embodiment to exhibit even better photodetection performance while enhancing the resolution.

It is to be noted that the effects described in the forgoing embodiments and the like are merely illustrative. The effects may be other effects, or the effects may further include other effects.

The present disclosure may have the following configuration.

<1>

A photodetector including:
a first photodetection unit configured to detect light in a first wavelength range;
a second photodetection unit stacked with the first photodetection unit and configured to detect light in a second wavelength range different from the light in the first wavelength range; and
one or a plurality of optical elements that is provided between the first photodetection unit and the second photodetection unit, and condenses the light in the second wavelength range that has passed through the first photodetection unit and guides the condensed light to the second photodetection unit.

The photodetector according to the forgoing <1>, in which a wavelength of the light in the second wavelength range is longer than a wavelength of the light in the first wavelength range.

<3>

The photodetector according to the forgoing <1> or <2>, in which
the light in the first wavelength range is visible light and the light in the second wavelength range is infrared light.
   <4>

The photodetector according to any one of the forgoing <1> to <3>, in which
the optical elements refract the light in the second wavelength range.
   <5>

The photodetector according to any one of the forgoing <1> to <4>, in which
the optical elements include a plurality of structural bodies of a size equal to or smaller than a wavelength of the light in the second wavelength range.
   <6>

The photodetector according to the forgoing <5>, in which each of the plurality of the structural bodies is a dielectric waveguide.

<7>

The photodetector according to the forgoing <5> or <6>, in which
each of the plurality of the structural bodies has a width and a height equal to or smaller than the wavelength of the light in the second wavelength range.
   <8>

The photodetector according to any one of the forgoing <5> to <7>, in which
the plurality of the structural bodies is arranged at a substantially constant pitch in an in-plane direction orthogonal to a direction in which the first photodetection unit and the second photodetection unit are superposed.
   <9>

The photodetector according to any one of the forgoing <1> to <4>, in which the optical elements include a condenser lens.

<10>

The photodetector according to the forgoing <9>, further including
a metal waveguide provided between the first photodetection unit and the second photodetection unit.
   <11>

The photodetector according to the forgoing <10>, in which
the metal waveguide is provided, in a plan view, along an outer edge of the second photodetection unit.
   <12>

The photodetector according to the forgoing <10> or <11>, in which
the metal waveguide includes a metal including aluminum (Al).
   <13>

The photodetector according to any one of the forgoing <1> to <4>, in which the optical elements include a metal waveguide.

<14>

The photodetector according to any one of the forgoing <1> to <4>, further including
a high refractive index material layer between the optical elements and the second photodetection unit.
   <15>

The photodetector according to any one of the forgoing <1> to <14>, in which the plurality of the optical elements is stacked with one another.

<16>

The photodetector according to any one of the forgoing <1> to <155>, in which the second photodetection unit includes:
a light-receiving unit that generates, by photoelectric conversion, carrier in accordance with an amount of received light; and
a multiplying unit that has a stacked structure of a first conductivity region and a second conductivity region, and avalanche-multiplies the carrier generated in the light-receiving unit.
   <17>

A ranging device including: an optical system; a photodetector; and a signal processing circuit that calculates a distance to an object of measurement based on an output signal of the photodetector,
the photodetector including
   a first photodetection unit configured to detect light in a first wavelength range;
   a second photodetection unit stacked with the first photodetection unit and configured to detect light in a second wavelength range different from the light in the first wavelength range; and
   an optical element that is provided between the first photodetection unit and the second photodetection unit, and condenses light that has passed through the first photodetection unit and guides the condensed light to the second photodetection unit.

This application claims the benefit of Japanese Priority Patent Application No. 2023-074996 filed with the Japan Patent Office on Apr. 28, 2023, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A photodetector, comprising:
a first photodetection unit configured to detect light in a first wavelength range;
a second photodetection unit stacked with the first photodetection unit and configured to detect light in a second wavelength range different from the light in the first wavelength range; and
one or a plurality of optical elements that is provided between the first photodetection unit and the second photodetection unit, and condenses the light in the second wavelength range that has passed through the first photodetection unit and guides the condensed light to the second photodetection unit.

2. The photodetector according to claim 1, wherein
a wavelength of the light in the second wavelength range is longer than a wavelength of the light in the first wavelength range.

3. The photodetector according to claim 1, wherein
the light in the first wavelength range is visible light and the light in the second wavelength range is infrared light.

4. The photodetector according to claim 1, wherein
the optical elements refract the light in the second wavelength range.

5. The photodetector according to claim 1, wherein
the optical elements include a plurality of structural bodies of a size equal to or smaller than a wavelength of the light in the second wavelength range.

6. The photodetector according to claim 5, wherein
each of the plurality of the structural bodies is a dielectric waveguide.

7. The photodetector according to claim 5, wherein
each of the plurality of the structural bodies has a width and a height equal to or smaller than the wavelength of the light in the second wavelength range.

8. The photodetector according to claim 5, wherein
the plurality of the structural bodies is arranged at a substantially constant pitch in an in-plane direction orthogonal to a direction in which the first photodetection unit and the second photodetection unit are superposed.

9. The photodetector according to claim 1, wherein
the optical elements include a condenser lens.

10. The photodetector according to claim 9, further comprising
a metal waveguide provided between the first photodetection unit and the second photodetection unit.

11. The photodetector according to claim 10, wherein
the metal waveguide is provided, in a plan view, along an outer edge of the second photodetection unit.

12. The photodetector according to claim 10, wherein
the metal waveguide includes a metal including aluminum (Al).

13. The photodetector according to claim 1, wherein
the optical elements include a metal waveguide.

14. The photodetector according to claim 1, further comprising
a high refractive index material layer between the optical elements and the second photodetection unit.

14. The photodetector according to claim 1, wherein
the plurality of the optical elements is stacked with one another.

16. The photodetector according to claim 1, wherein the second photodetection unit includes:
a light-receiving unit that generates, by photoelectric conversion, carrier in accordance with an amount of received light; and
a multiplying unit that has a stacked structure of a first conductivity region and a second conductivity region, and avalanche-multiplies the carrier generated in the light-receiving unit.

17. A ranging device, comprising: an optical system; a photodetector; and a signal processing circuit that calculates a distance to an object of measurement based on an output signal of the photodetector,
the photodetector including
a first photodetection unit configured to detect light in a first wavelength range;
a second photodetection unit stacked with the first photodetection unit and configured to detect light in a second wavelength range different from the light in the first wavelength range; and
an optical element that is provided between the first photodetection unit and the second photodetection unit, and condenses light that has passed through the first photodetection unit and guides the condensed light to the second photodetection unit.
